(19) United States
(12) Patent Application Publication
(10) Pub. No.: US 2011/0097533 A1
(43) Pub. Date: Apr. 28, 2011

(54) THIN FILM ENCAPSULATION METHOD

(75) Inventors: Feng Li, Oxnard, CA (US); Wenming Su, Suzhou City (CN)

(73) Assignee: SUNA DISPLAYS CO., LTD., Suzhou City (CN)

(21) Appl. No.: 12/912,451

(22) Filed: Oct. 26, 2010

(30) Foreign Application Priority Data
Oct. 27, 2009 (CN) 200910209246.9

(51) Int. Cl. B32B 3/02; C23C 16/513; B32B 7/02

(52) U.S. Cl. 428/68; 427/578

(57) ABSTRACT

This invention discloses a thin film encapsulation method, which applies a PECVD method, deposition thin film on the device surface to separate the devices' active area from the water vapor and oxygen in the air, so as to realize the physical protection and thus to accomplish the device encapsulation, specifically, comprising the following procedures: (1) Placing the devices to be encapsulated in the PECVD chamber, and fixing the mask to control the encapsulation area; (2) Depositing the inorganic layer, the polymer layer and the graded composition layer by using the organic silica precursor through the PECVD method under the plasma condition and obtain the required encapsulation structure.

### CROSS-REFERENCES TO RELATED APPLICATIONS

This application claims priority from Chinese Patent Application Number 200910209246.9, filed on Oct. 27, 2009 in its entirety.

This invention relates to a thin film encapsulation structure and method, especially relates to a thin film encapsulation structure and method of monitors, diodes, micro electro-mechanical sensors and organic light emitting diodes (OLED), etc.

### BACKGROUND

Most components like monitors, diodes and micro electro-mechanical diodes all require hermetically physical sealing.

As shown by research, many constituents in the air such as water vapor and oxygen have a great influence on the lifetime of an OLED. The reasons are as follows: while the OLED is working, electrons are injected from the cathode, which requires that the work-function of the cathode is low enough to efficiently cause injection. However, the metal used as the cathode such as aluminum, magnesium or calcium is relatively reactive to the permeated both water vapor and oxygen. Besides, the water vapor will react to the hole transport layer and the electron transport layer (ETL) material and thus cause the failure of device. Therefore, fine encapsulation of an OLED to protect the functional layers of the device from the water vapor and oxygen in the air will increase the lifetime of the device. For example, organic photoelectric components like organic light emitting displays (OLED), organic photovoltaic devices and organic solar cells are sensitive to the vapor and oxygen in the air, for vapor and oxygen will directly influence the service lifetime and work efficiency. In order to relieve the damage of water vapor and oxygen to influence the lifetime and performance of devices, the organic photoelectric devices should be encapsulated.

Traditionally, electrodes and organic functional layers of OLED are fabricated on a rigid substrate (glass, metal), and the encapsulation including the sealing a plate cover on the rigid substrate with epoxy resin by thermally or ultraviolet (UV) irradiation. Then, a sheathing is formed between the rigid substrate and the plate cover, which separates the devices and the air, and the water vapor and oxygen in the air will penetrate through the epoxy resin to the device active areas. Therefore, the reactions between the organic layers/cathode of OLED and the water vapor/oxygen in the air are effectively prevented.

However, along with the micromation of devices and the development of some new and environment-sensitive devices, such encapsulation method is to some degree limitative. For example, as for a small device, the encapsulation with the encapsulation cover and epoxy resin is difficult and inefficient with high cost.

Furthermore, the encapsulation of flexible OLED, on the one hand, the vapor permeability of the encapsulation structure should be lower than 5×10−6 g·m-2/d, and oxygen lower than 10−5 cm2·m-2/d; on the other hand, the encapsulation cover should satisfy the requirements of flexibility. As for the traditional encapsulation method of OLED, the UV encapsulant cannot fulfill the request of impermeability, so some desiccants or getters should be added to remove the water vapor and oxygen in the devices active area; and on the other hand, such rigid encapsulation covers cannot meet the requirement of flexibility.

Thus, the flexible OLED devices usually use the thin film encapsulation, which physically protects the core area of devices by forming a compact structure sealing thin film. It is a gapless thin film encapsulation that adds almost no weight and volume to devices. The usual materials for thin film encapsulation mainly include thin polymer film, metal thin film and inorganic insulating thin film, etc. The thin polymer films are flexible but most of them are inadequate as water vapor/oxygen barrier for use in protecting organic photoelectric devices. The conductivity and opacity of the metal thin film limits its application for device encapsulation. And although the inorganic insulating thin films like SiOx and SiNx has relative high barrier performance for water vapor and oxygen penetration, their rigid structure is not suitable for the encapsulation of flexible devices. According to the number of seal layers, there are two encapsulation patterns, that is, single-layer and multi-layer encapsulations. If the organic electroluminescent cell is encapsulated with single-layer thin film, the inorganic thin film without interstitial spaces should be applied to guarantee the barrier performance, but the flexibility is difficult to be realized. Researchers have developed the above-mentioned complex thin film encapsulation techniques, such as polymer-metal and polymer-SiOx, etc., and this technique not only enhances the barrier performance, but also effectively improves the performance of the thin film, for example, the flexibility of the structure. If the polymer-SiOx structure is used in organic photoelectronic devices, after the metal cathode deposition, a layer of intensive SiOx or SiNx is directly deposited upon the organic area and form polymer above the SiOx layer by different methods in two deposition chambers. Such repetition will forge the multi-layer alternately structure of SiOx (SiNx)/polymer/SiOx (SiNx) /polymer, protecting devices and isolating it from the corrosion of water and oxygen. The weakness is originated from the different treatments in two chamber with many procedures and long cycles. The production of SiOx or SiNx thin film applying frequently used methods like PVD, CVD, high-vacuum thermal deposit and magnetron sputtering requires high temperature, which is to some extent harmful to the device.

### SUMMARY OF THE INVENTION

The object of the present invention is to provide a thin film encapsulation method, so as to meet the encapsulation requirements of permeate barrier and flexibility, and, at the same time, decrease the operative procedures, shorten the treatment cycle and reduce the damage to the organic layer during the encapsulation.

This object is achieved according to the technical scheme of this invention described below in which a thin film encapsulation method, using plasma enhanced chemical vapor deposition (PECVD) so as to produce thin film on a device's surface to separate the device from the water vapor and oxygen in the air and thus realize the physical protection and encapsulate the device, comprising the following steps:

(1) Placing the device to be encapsulated in the PECVD chamber, and fixing the mask to control the encapsulation area; (2) Adjusting the gas flow injected into the PECVD chamber and alternately depositing the polymer layer and the inorganic layer by using the organic silicon precursor through the PECVD method; (3) Repeating Step (2) for 2-20 times. In the technical scheme above, the method of the aforementioned depositing the polymer layer step comprises the following procedures: applying the PECVD method and depositing the organic layer under the plasma condition in the oxygen-free and nitrogen-free atmosphere;

The method of the aforementioned depositing the inorganic layer step comprises the following procedures: adjusting the gas flow in the PECVD chamber, applying the PECVD method and depositing the inorganic layer under the plasma condition in the nitrogen-rich or/and oxygen-rich atmosphere.

In the technical scheme above, the organic silica precursor is selected from one of the organic siloxane compounds which can be fragmented in the plasma environment. In the preferred embodiment of this invention, the organic silica precursor is selected from one of: tetraethyl orthosilicate (TEOS), hexamethyldisiloxane (HMDSO), octamethylcy-clotetrasiloxane (OMCTS) or tetramethylbenzene cyclotetrasiloxane (TMCTS). Characterized as environmental protective and safe, these materials have been widely used.

In the technical scheme above, in said Step (2), while applying the PECVD method to alternately deposit the polymer layer and the inorganic layer, the density of the plasma is between 1011˜1012/cm³ and the electron temperature of the plasma is 2˜7 eV. In the preferred embodiment of this invention, the plasma source is electron cyclotron resonance (ECR) or inductively coupled plasma (ICP).

In the technical scheme above, and in the preferred embodiment of this invention, said nitrogen-rich or/and oxygen-rich atmosphere refers to the partial pressure of nitrogen or/and oxygen occupies more than ⅔ of the total pressure in the PECVD chamber.

In the preferred technical scheme of this invention, depositing a thin inorganic layer on the surface of the object area of the devices to be encapsulated first, then taking Step (2).

In the technical scheme above, every said polymer layer is 5 nm˜2 μm thick; the main composition of the polymer is cross-linking organic silicone with the structural unit of such as (—CH2—SiH2—CH2—SiH2—); said the inorganic layer is 5 nm˜2 μm thick; and when the atmosphere in the PECVD chamber is oxygen-rich, the main composition of the inorganic layer is SiOx thin film; when the atmosphere in the PECVD chamber is nitrogen rich, the main composition of the inorganic layer is SiNx thin film; and when the atmosphere in the PECVD chamber is oxygen and nitrogen existence, the main composition of the inorganic layer is SiOxNy thin film.

Another object of the present invention is to provide a thin film encapsulation structure obtained according to the above mentioned thin film encapsulation method, wherein said the thin film encapsulation structure is composed by the alternately set polymer layer and inorganic layer, every polymer layer is 5 nm˜2 μm thick, and the number of polymer layers ranges from 2˜20; every inorganic layer is 5 nm˜2 μm, and the number of inorganic layers ranges from 2˜20; the main composition of the polymer layer is cross-linking organic silicone with the structural unit of (—CH2—SiH2—CH2—SiH2—); the main composition of the inorganic layer is any one of: SiOx thin film, SiNx thin film or SiOxNy thin film.

In the further technical scheme, aforementioned thin film encapsulation method further comprises step of setting a graded composition layer between every neighboring polymer layer and the inorganic layer to reduce the stress between neighboring layers interface, which includes the following steps: adjusting the gas in the PECVD chamber, making the partial pressure of oxygen and/or nitrogen occupy 0˜⅔ of the total pressure in the PECVD chamber, and depositing the graded composition layer under the plasma condition by using the organic silicon precursor through the PECVD method.

In the technical scheme above, wherein setting a graded composition layer between the neighboring inorganic layer and the polymer layer includes two situations: (1) setting a graded composition layer from the inorganic layer to the polymer layer; (2) setting a graded composition layer from the inorganic layer to the polymer layer; while setting a graded composition layer from the polymer layer to the inorganic layer, during the deposition of the graded composition layer, the occupation of the partial pressure of nitrogen or/and oxygen will be increased from 0 to ⅔ of the total pressure in the PECVD chamber; while setting a graded composition layer from the inorganic layer to the polymer layer, during the deposition of the graded composition layer, the occupation of the partial pressure of nitrogen or/and oxygen will be decreased from ⅔ to 0 of the total pressure in the PECVD chamber.

In the technical scheme above, wherein said the graded composition layer is cross-linking organic and inorganic hybrid thin film; when there is no nitrogen but oxygen in the PECVD chamber, the cross-linking organic and inorganic hybrid is Py(SiOx)1-y; when there is no oxygen but nitrogen in the PECVD chamber, the cross-linking organic and inorganic hybrid is Py(SiNx)1-y; and when nitrogen and oxygen coexist in the PECVD chamber, the cross-linking organic and inorganic hybrid is Py(SiOx)z(SiNx)1-y-z, wherein P refers to cross-linking polymer organic silicone with the structural unit of (—CH2—SiH2—CH2—SiH2—), 0<y<1.0≦z≦1, in the graded composition layer structure, the value of y varies as the functional relation (commonly arithmetic progression) along with the growth of the thin film with the value decreasing from 1 to 0 progressively; and the thickness of the graded composition layer is between 5 nm˜100 nm.

A thin film encapsulation structure obtained according to the above mentioned thin film encapsulation method, is composed with the alternately set-up polymer layer and the inorganic layer, and a graded composition layer set between the neighboring polymer layer and inorganic layer; said graded composition layer is the cross-linking organic and inorganic hybrid thin film; and said cross-linking organic and inorganic hybrid is any one of: Py(SiOx)1-y, Py(SiNx)1-y or Py(SiOx)z(SiNx)1-y-z, wherein P refers to cross-linking polymer organic silicone with the structural unit of (—CH2—SiH2—CH2—SiH2—), 0<y<1.0≦z≦1, and the thickness of the graded composition layer is between 5 nm˜100 nm.

In the prefer technical scheme of the OLED thin film encapsulation, a layer of CuPc protection film with the thickness of 100 nm should be set up between the encapsulation thin film and the to-be-encapsulated devices before encapsulation process, that is, after the OLED devices being fabricated, a layer of CuPc protection film with the thickness of 100 nm should be deposited under the vacuum condition in the to-be-encapsulated area so as to prevent the devices from being damaged in the encapsulation process.

The fundamental principle of this invention is: the electrons in the high density plasma source bombard the organic silica precursor molecular and make the raw material of the organic silica precursor used for fragment. The fragments have a chemical reaction and get cross-linking, then deposition on surface of devices as thin film. And when the gas species in the PECVD chamber changes, the obtained thin film will be changed correlatively, and thus, there will be the inorganic layer, the polymer layer and the graded composition layer accomplished in a same chamber. The inorganic layer will provide mechanical strength and fine permeate barrier; the polymer layer will provide fine flexibility; and the graded composition layer will have the characters of both the inorganic layer and the polymer layer. Besides, the temperature on the surface of the devices during the entire reaction will lower than 100° C. so as to effectively avoid the damage of heat to the devices during the encapsulation.

The advantage of this encapsulation method is the great amount of polymer in the encapsulation layer, which is flexible. The interface between the devices and the encapsulation film is organic matter/organic matter, or inorganic matter/inorganic matter without stress. The encapsulation layer has the graded structure from flexible polymer to rigid silicon oxide without obvious stress, so the mechanical structure is quite stable. Furthermore, the joint actions of the polymer layer and the inorganic layer can be effectively waterproof and oxygen isolated.

Due to the application of the above mentioned technical scheme, this invention has the following advantages compared with the existing techniques:

(1) The invention applies the PECVD method, which can accomplish the preparation of the polymer layer, the inorganic layer and the graded composition layer so as to greatly simplify the encapsulation procedures, decrease the cost, shorten the processing cycle and thus save the production cost in effect; And the encapsulation layer possesses great amount of polymer or graded composition layer, containing compositions varying from the flexible polymer to silicon dioxide or silicon nitride. The sufficient flexibility without the influence of the interface stress is suitable for the encapsulation of the flexible organic photoelectronic devices;

(2) The invention uses gapless thin film encapsulation and the prepared thin film does not add to the weight and volume of the devices. It has high density, and fine capability of insulating the water vapor and oxygen in the air. Therefore, the absence of drying films will reduce the thickness of the encapsulation layer. Besides, the encapsulation layer is strong enough to protect the organic layer from being harmed while encapsulating the organic photoelectronic devices like OLED;

(3) This invention applied the vapor deposition, which will accomplish the thin film growth on the surface of the 3d structure, and thus can be used for the encapsulation of special devices with the 3d structured external surface.

### BRIEF DESCRIPTION OF THE DRAWINGS

FIG. 1: Schematic drawing of the PECVD chamber in Selected Embodiment 1;

FIG. 2: Schematic drawing of the alternate encapsulation structure of the inorganic layer\polymer layer in Selected Embodiment 1;

FIG. 3: Schematic drawing of the encapsulation structure of the inorganic layer\graded composition layer\polymer layer in Selected Embodiment 3; wherein, 1. polymer layer; 2. inorganic layer; and 3. graded composition layer.

### DETAILED DESCRIPTION OF THE PREFERRED EMBODIMENTS

This invention will be best understood with reference to the following description of example embodiments.

### EXAMPLE 1

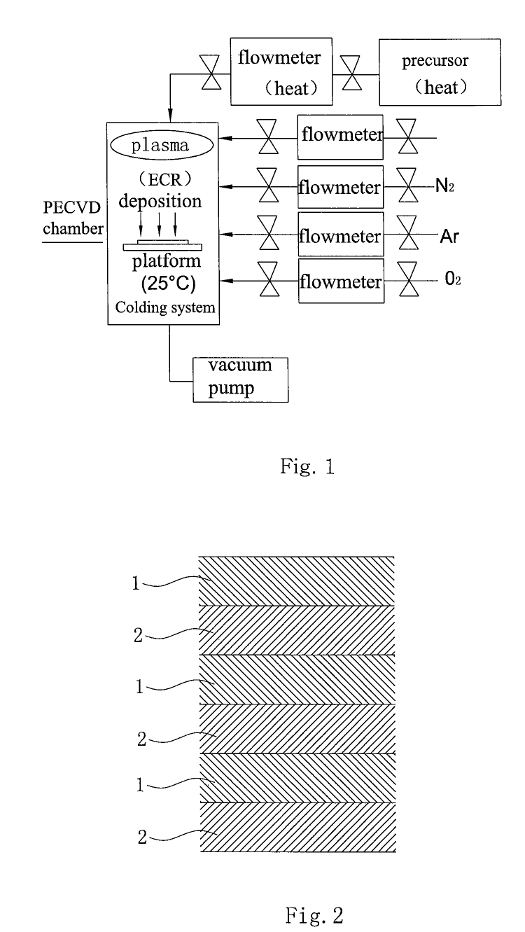

After the preparation of the OLED devices, firstly, in vacuum condition, deposit a 100 nm thick CuPc protection film on the aluminum electrode to prevent the devices from being harmed during the encapsulation. Then, transfer the OLED devices to the PECVD chamber (as FIG. 1) used for encapsulation without exposure to air. The diameter of the PECVD chamber is about 200 nm, cylindrical and 200 mm tall. The devices are placed on the rigid substrate upwards, and a mask is used to control the encapsulation area. Evacuate the cavity to 1.5 Pa and inject hexamethyldisiloxane (HMDSO), adjust the radio intensity to 60 mA under the plasma condition (electron cyclotron resonance, ECR, with the frequency of 40 KHz), and deposition the organic silicone polymer thin film under the Ar gas carrying condition for one minute with the internal pressure of 6 Pa. Next, turn off the plasma source, stop injecting Ar gas and inject oxygen to vary the internal pressure to 6 Pa. Turn on the plasma source and let the deposition last for one minute to complete the deposition of the inorganic layer silicon dioxide. Moreover, adjust the previously mentioned polymer growth conditions, and grow the polymer layer and then inorganic silicon dioxide. Repeat this step for five times and accomplish the encapsulation structure (as FIG. 2) of the multiple overlapping of the organic layer/inorganic layer. The advantage of the encapsulation is that the great amount polymer contained in the encapsulation layer is flexible. The interface between the devices and the encapsulation film is organic/inorganic matter, almost without stress, so it is mechanically stable.

### EXAMPLE 2

Carry out the characterization test to the Alq3 OLED devices prepared on the ITO glass substrate encapsulated by applying the method described in Example 1, and compare it with the traditional glass covered epoxide resin encapsulation in lifetime and efficiency, the result shows that: the devices encapsulated with this method have almost the same efficiency to epoxide resin encapsulated devices, which reveals that this encapsulation is harmless to the devices performance. If there is no CuPc layer deposition before the OLED encapsulation, it will be slightly harmful. As for the lifetime test, the lifetime of the glass encapsulation component is 3000 h, while the lifetime of component in this invention exceeds 3000 h. This illustrates that this invention has the generally equal water and oxygen isolation capability to the glass covered epoxide resin encapsulation.

### EXAMPLE 3

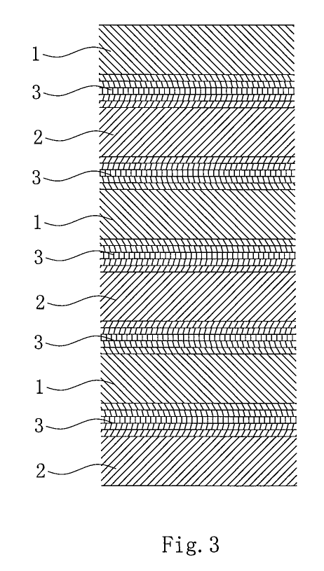

After finishing the preparation of the OLED devices in vacuum condition, deposit a 100 nm thick CuPc protection film on the aluminum electrode to prevent the devices from being harmed during the encapsulation. Then, transfer the OLED devices to the PECVD chamber used for encapsulation in the inert atmosphere. A mask is used to control the encapsulation area. Meanwhile, place a 1 μm thick thin steel plate beside the devices in order to grow the completely same encapsulation thin film on the steel plate while encapsulating the devices. Pump the chamber to 1.5 Pa and inject hexamethyldisiloxane (HMDSO), adjust the radio intensity to 60 mA under the plasma condition (electron cyclotron resonance, ECR, with the frequency of 40 KHz), and grow the organic silicon polymer thin film under the Ar gas carrying condition for one minute with the internal pressure of 8 Pa. Then, increase the NH3 gas gradually as 50 SCCM every 5 seconds to 200 SCCM and decrease the Ar flow as 50 SCCM every 5 seconds to grow the graded composition layer of organic and inorganic hybrid. Next, let the deposition continue for 30 seconds under the NH3-rich atmosphere. Then, increase the Ar flow gradually as 50 SCCM every 5 seconds to 200 SCCM and decrease the NH3 flow as 50 SCCM every 5 seconds to deposit the graded composition layer of organic and inorganic hybrid. And let the graded composition layer grow. Repeat this cycle for 5 times and complete the encapsulation structure of the organic and inorganic overlapping with the graded composition layer (as FIG. 3).

### EXAMPLE 4

Test the thin film over the steel plate in Example 3, and the total thickness of the encapsulation thin film is 1.2 μm. Flexually deform the steel plate and discover no crack on the encapsulation thin film by examination. Carry out the characterization test to the OLED which is encapsulated by applying the method described in Example 3, and compare it with the traditional glass covered epoxide resin encapsulation in lifetime and efficiency, the result shows that: the devices encapsulated with this method have almost the same efficiency to epoxide resin encapsulated devices, which reveals that this encapsulation is harmless to the devices. As for the lifetime test, the lifetime of the glass encapsulation component is 3000 h, while the lifetime of derive in this invention exceeds 3000 h. This illustrates that this invention has the generally equal water and oxygen isolation capability to the glass covered epoxide resin encapsulation. The advantage of this invention is that the inorganic layer of the encapsulation layer is silicon nitride, and the density is higher than silicon dioxide. The interface between the devices and the encapsulation film is organic/inorganic matter, basically without the influence of pressure. The encapsulation layer is the silicon nitride encapsulation structure from the flexible polymer to rigid silicon nitride without obvious pressure, so it is mechanically stable with better flexibility.

We claim:

1. A thin film encapsulation method comprising the following steps:
(1) Placing device samples to be encapsulated in a PECVD chamber, and fixing a mask to control an encapsulation area;
(2) Adjusting a gas flow injected into the PECVD chamber and alternately depositing a polymer layer and an inorganic layer by using an organic silica precursor; and
(3) Repeating Step (2) for 2-20 times.

2. The thin film encapsulation method of claim 1, wherein the method of said depositing the polymer layer comprises:
applying the PECVD method and depositing the organic layer under the plasma condition in the oxygen-free and nitrogen-free atmosphere;
wherein the depositing the inorganic layer comprises the following procedures: adjusting the gas flow in the PECVD devices, applying the PECVD method and depositing the inorganic layer under the plasma condition in the nitrogen-rich or/and oxygen-rich atmosphere.

3. The thin film encapsulation method of claim 1, wherein in said Step (2), while applying the PECVD method to alternately deposit the polymer layer and the inorganic layer, the density of plasma is between 1011˜1012/cm³ and the electron temperature of the plasma is 2˜7 eV.

4. The thin film encapsulation method of claim 2, wherein said nitrogen-rich or/and oxygen-rich atmosphere refers to the partial pressure of nitrogen or/and oxygen occupies more than ⅔ of the total pressure in the PECVD chamber.

5. The thin film encapsulation method of claim 2, wherein every said polymer layer is 5 nm˜2 μm thick;
the main composition of the polymer is cross-linking organic silicone with the structural unit of (—CH2—SiH2—CH2—SiH2—);
said the inorganic layer is 5 nm˜2 μm thick; and when the atmosphere in the PECVD devices is oxygen-rich, the main composition of the inorganic layer is SiOx; when the atmosphere in the PECVD devices is nitrogen-rich, the main composition of the inorganic layer is SiNx; and
when the atmosphere in the PECVD devices is oxygen and nitrogen, and the main composition of the inorganic layer is SiOxNy thin film.

6. The thin film encapsulation method of claim 2, further comprising step of setting a graded composition layer between the neighboring inorganic layer and the polymer layer, which include the following steps:
adjusting and controlling a ratio and flow of oxygen or/and nitrogen of mixed gas in the PECVD chamber, making the partial pressure of oxygen or/and nitrogen occupy 0˜⅔ of the total pressure in the PECVD chamber, and
depositing the graded composition layer under the plasma condition by using the organic silica precursor through the PECVD method.

7. The thin film encapsulation method of claim 6, wherein setting a graded composition layer between the neighboring inorganic layer and the polymer layer includes one of two situations:
(1) setting a graded composition layer from the inorganic layer to the polymer layer;
(2) setting a graded composition layer from the inorganic layer to the polymer layer; while setting a graded composition layer from the polymer layer to the inorganic layer, during the deposition of the graded composition layer, the occupation of the partial pressure of nitrogen or/and oxygen will be increased from 0 to ⅔ of the total pressure in the PECVD chamber; while setting a graded composition layer from the inorganic layer to the polymer layer, during the deposition of the graded composition layer, the occupation of the partial pressure of nitrogen or/and oxygen will be decreased from ⅔ to 0 of the total pressure in the PECVD chamber.

8. The thin film encapsulation method of claim 6, wherein said the graded composition layer is cross-linking organic and inorganic hybrid thin film; when there is no nitrogen but oxygen in the PECVD chamber, the cross-linking organic and inorganic hybrid is Py(SiOx)1-y;
when there is no oxygen but nitrogen in the PECVD chamber, the cross-linking organic and inorganic hybrid is Py(SiNx)1-y; and
when nitrogen and oxygen coexist in the PECVD chamber, the cross-linking organic and inorganic hybrid is Py(SiOx)z(SiNx)1-y-z; wherein P refers to cross-linking polymer organic silicon with the structural unit of (—CH2—SiH2—CH2—SiH2—), 0<y<1.0≦z≦1; and the thickness of the graded composition layer is between 5 nm˜100 nm.

9. A thin film encapsulation structure, wherein said the thin film encapsulation structure is composed by the alternately set polymer layer and inorganic layer, every polymer layer is 5 nm˜2 μm thick, and the number of polymer layers ranges from 2˜20; every inorganic layer is 5 nm˜2 μm, and the number of inorganic layers ranges from 2˜20;
the main composition of the polymer layer is cross-linking organic silicone with the structural such as unit of (—CH2—SiH2—CH2—SiH2—); the main composition of the inorganic layer is any one of: SiOx thin film, SiNx thin film or SiOxNy thin film.

10. A thin film encapsulation structure of claim 9, further comprising a graded composition layer between every neighboring polymer layer and the inorganic layer, said the graded composition layer is the cross-linking organic and inorganic hybrid thin film; and
said cross-linking organic and inorganic hybrid is any one of: Py(SiOx)1-y, Py(SiNx)1-y or Py(SiOx)z(SiNx)1-y-z, wherein P refers to cross-linking polymer organic silicon with the structural unit of (—CH2—SiH2—CH2—SiH2—), 0<y<1.0≦z≦1, and the thickness of the graded composition layer is between 5 nm˜100 nm.
